(19) United States
(12) Patent Application Publication
(10) Pub. No.: US 2007/0000690 A1
(43) Pub. Date: Jan. 4, 2007

(54) Printed circuit board assembly and method for preventing EMI of crystal oscillator thereof

(75) Inventor: Qing-Li Chai, SuZhou City (CN)

Correspondence Address: RABIN & Berdo, PC, 1101 14TH STREET, NW, SUITE 500, WASHINGTON, DC, 20005, US

(73) Assignee: BenQ Corporation

(21) Appl. No.: 11/473,051

(22) Filed: Jun. 23, 2006

(30) Foreign Application Priority Data
Jul. 1, 2005 (TW) 94122396

(51) Int. Cl. H05K 1/11

(52) U.S. Cl. 174/260; 174/262; 257/774

(57) ABSTRACT

A printed circuit board Assembly (PCBA), including at least one crystal oscillator and a printed circuit board (PCB), is provided. The crystal oscillator includes a body and a shell. The shell covers the body. The PCB includes at least one inserting area and at least one plated hole. The inserting area is used for receiving the body. The plated hole is disposed on the inserting area. When the PCBA is under wave soldering process, the solder is drawn from one side of the PCBA to another side via the plated hole for enabling the shell to be electrically connected to the bare copper of the inserting area via the solder. Consequently, the shell has an even better shielding effect, and the EMI effect is reduced.

This application claims the benefit of Taiwan application Serial No. 94122396, filed Jul. 1, 2005, the subject matter of which is incorporated herein by reference.

### BACKGROUND OF THE INVENTION

1. Field of the Invention

The invention relates in general to a printed circuit board assembly (PCBA) and a manufacturing method thereof, and more particularly to a PCBA capable of preventing EMI effect of a crystal oscillator and a manufacturing method thereof.

2. Description of the Related Art

Crystal oscillators, which have now been widely applied in various systems, are aimed at providing a standard of reference for the oscillation frequency of the system. However, crystal oscillators, which often generate high oscillation frequency during oscillation, would easily result in electrical magnetic interference (EMI) effect. If the EMI effect is too large, the efficiency of the PCBA or the entire system would be affected. A method for preventing EMI effect of a crystal oscillator is disclosed below.

Referring to FIG. 1, the relationship between a crystal oscillator and a PCBA is shown. The PCBA 100 reserves an inserting area 101. The inserting area 101 has two holes 105a and 105b and a pre-soldering area 107. The crystal oscillator 103 has two pins 108a and 108b positioned inside the inserting area 101. The two pins 108a and 108b are respectively inserted into the two holes 105a and 105b. In order to reduce EMI effect, normally the inserting area 101 is designed as a ground bare copper, so that the shell of the crystal oscillator' 103 is electrically connected to the ground bare copper after the pins 108a and 108b of the crystal oscillator 103 are inserted into the holes 105a and 105b. The shell has better shielding effect when grounded. The wave soldering process is applied to fix the inserting component on the PCBA after the pins 108a and 108b are inserted into the PCBA 100. However, the wave soldering process would make the crystal oscillator 103 crippled, affecting the contact between the shell of the crystal oscillator 103 and the ground bare copper of the inserting area and deteriorating the shielding effect. To avoid such a problem so that a better shielding effect can be achieved, the current practice adopts manual soldering to connect the shell of the crystal oscillator 103 to the ground bare copper of the pre-soldering area 107 after the wave soldering process. By doing so, the shell of the crystal oscillator 103 has an even better shielding effect, the components inside the crystal oscillator 103 are better protected, and the EMI effect is reduced.

However, the additional manual soldering process is both labor and time consuming. Besides, the components surrounding the crystal oscillator could be damaged due to carelessness in soldering process.

### SUMMARY OF THE INVENTION

It is therefore an object of the invention to provide a method promptly and correctly enabling the shell of the crystal oscillator to be connected to the ground layer of the PCBA without using manual soldering process, thereby reducing the EMI effect of the crystal oscillator.

The invention achieves the above-identified object by providing a PCBA including a crystal oscillator and a print circuit board (PCB). The crystal oscillator includes a body and a shell. The shell covers the body. The PCB includes an inserting area and at least a plated hole. The inserting area is used for receiving the body. The inserting area disposed on one side of the PCBA is used for receiving the crystal oscillator. The inserting area is designed as a ground bare copper and includes a pre-soldering area. The plated hole is disposed on the pre-soldering area. The inner surface of the plated hole is electroplated with a coating of conductive metal for guiding the solder. The ground layer is electrically connected to the shell via the solder for enabling the shell to be connected to the ground layer, so that the EMI effect is reduced. Besides, the plated hole is able to be electrically connected to other ground layers of the PCBA, so that the grounded area of the shell is increased and the shielding effect is enhanced.

The invention further achieves the above-identified object by providing a method for fixing a crystal oscillator on a PCB to prevent EMI effect. The crystal oscillator has a shell. The PCB has an inserting area. The method includes the following steps. Firstly, a PCB is provided. The PCB has a plated hole. The inner surface of the plated hole is electroplated with a coating of conductive metal. The crystal oscillator and other inserting components are inserted into the corresponding inserting areas on the PCB. Then, wave soldering process is applied to the PCBA, so that the solder is drawn from another side of the PCB to one side of the crystal oscillator on which the crystal oscillator is disposed via the plated hole and passes through the PCB from bottom to up, and that the shell of the crystal oscillator is electrically connected to the ground layer of the PCBA.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a diagram showing the relationship between a crystal oscillator and a PCBA;

FIG. 2A is a diagram showing the relationship between a crystal oscillator and a PCBA according to the first embodiment of the invention;

FIG. 2B is a 3-D diagram of a crystal oscillator;

FIG. 2C is a top view of an inserting area and a pre-soldering area;

FIG. 2D is a top view of a pre-soldering area having various numbers of plated holes;

FIG. 2E is a schematic view of a plated hole;

FIG. 3A is a top view of plated holes and a crystal oscillator according to the second embodiment of the invention;

FIG. 3B is a cross-sectional view of the crystal oscillator of FIG. 3A; and

FIG. 4 is a flowchart showing the technology of the invention.

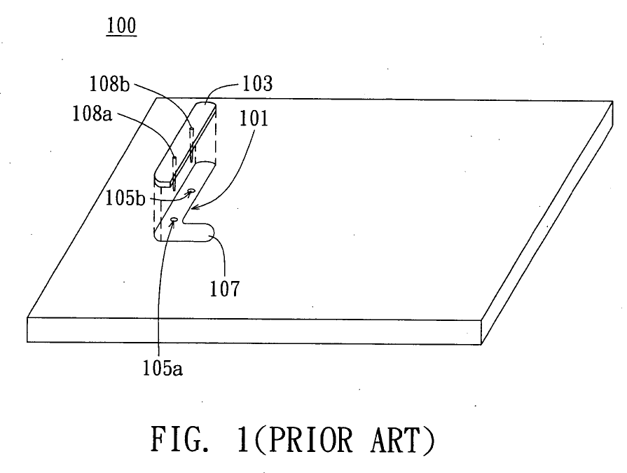

### DETAILED DESCRIPTION OF THE INVENTION

### First Embodiment

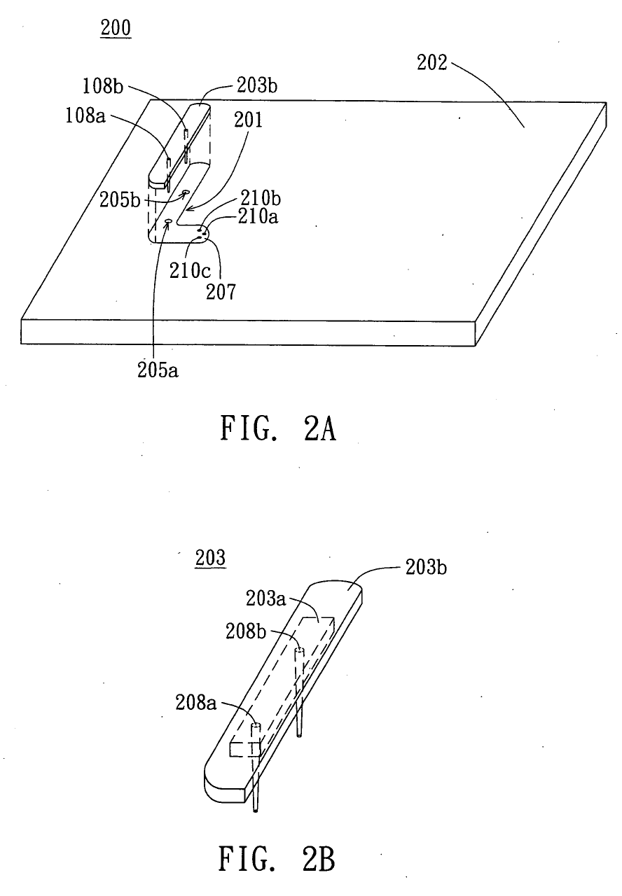

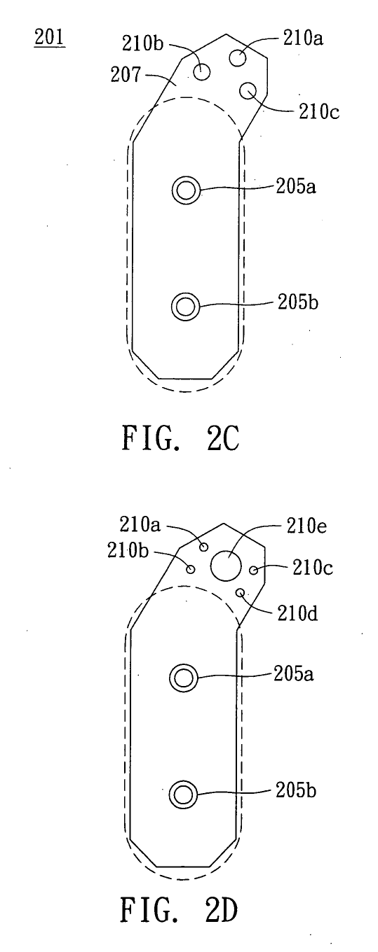

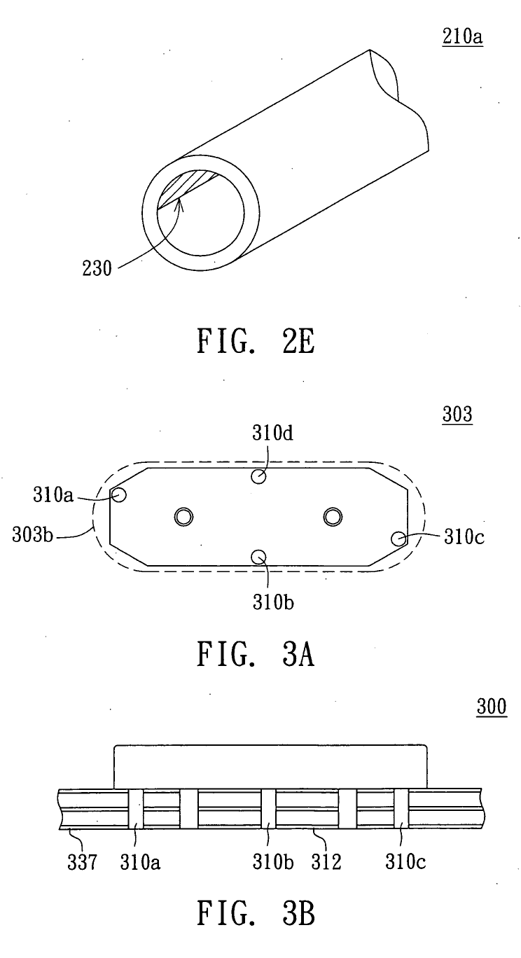

Referring to FIG. 2A, FIG. 2B and FIG. 2C at the same time. FIG. 2A is a diagram showing the relationship between a crystal oscillator and a PCBA according to the first embodiment of the invention. FIG. 2B is a 3-D diagram of a crystal oscillator. FIG. 2C is a top view of an inserting area and a pre-soldering area. The PCBA 200 includes a crystal oscillator 203 and a PCB 202 (the print circuit board, PCB). The PCB 202 reserves an inserting area 201. The inserting area 201 has a pre-soldering area 207. The pre-soldering area 207 has several plated holes 210a-210c. The pre-soldering area 207 includes metal, and preferably the metal is bare copper. The inserting area 201 has two holes 205a and 205b, and the inserting area 201 is disposed on one side of the PCBA 200. The crystal oscillator 203 has the body 203a and the shell 203b. The shell 203b covers the body 203a for protecting the electronic components inside the body 203a. Meanwhile, the crystal oscillator 203 further includes two pins 208a and 208b. The two pins 208a and 208b are respectively inserted into the holes 205a and the holes 205b. The plated holes 210a-210c can be of any shapes such as the circular shape illustrated in FIG. 2C.

Referring to FIG. 2D, a top view of a pre-soldering area having various numbers of plated holes is shown. The plated hole can be of any shapes, and the number of the plated hole is determined according to actual needs in soldering process. The plated hole (such as 210e) would produce better soldering effect if the plated hole has a wider diameter and is disposed close to the shell. During actual operation, the crystal oscillator 203 would generate high-frequency signals. Therefore, the crystal oscillator 203 having high-frequency signals would easily generate EMI effect. However, EMI effect would easily cause the shell 203b and the surrounding electronic components such as chips and capacitors to generate stray capacitance effect. The stray capacitance effect would easily generate currents and affect the normal operation of the entire PCBA 200. Therefore, the metal shell 203b of the crystal oscillator 203 is electrically connected to the pre-soldering area 207 of the PCBA via the solder. The pre-soldering area 207 is grounded. Each of the inner surfaces of the plated holes 210a-210e is an electroplated coating of metal, and can be electrically connected to other ground layers of the PCBA 200 for enabling the shell 203b to be grounded more efficiently. Through the aforementioned mechanism, EMI effect is effectively reduced, and shielding effect of the shell is incorporated to protect the electronic components inside the crystal oscillator 203 as well as the electronic components outside the PCBA 200. Furthermore, referring to FIG. 2E, a diagram of a plated hole is shown. For any plated hole such as the plated hole 210a for instance, the inner surface 230 of the plated hole 210a is electroplated with a coating of metal having high conductivity such as copper for instance, so that the conductivity efficiency is enhanced.

### Second Embodiment

In the aforementioned embodiment, for the convenience of checking the reliability that the plated hole electrically connects the shell and the ground layer via the solder, the plated hole is disposed close to the surface of the shell. Under stable and reliable conditions of technology, the invention can be achieved by another embodiment.

Referring to both FIG. 3A and FIG. 3B. FIG. 3A is a top view of plated holes and a crystal oscillator according to the second embodiment of the invention, and FIG. 3B is a cross-sectional view of the crystal oscillator of FIG. 3A. The plated holes 310a-310d are disposed under the crystal oscillator 303, thus omitting the pre-soldering area and reducing the area of the PCBA. That is, the plated holes 310a-310d are directly connected to each ground layer of the PCBA 300. For example, the plated holes 310a-310d are connected to the ground layer 312. In the present embodiment, the closer to the shell 303b the plated holes 310a-310d are disposed, the better the effect of guiding the currents to the ground layer will be.

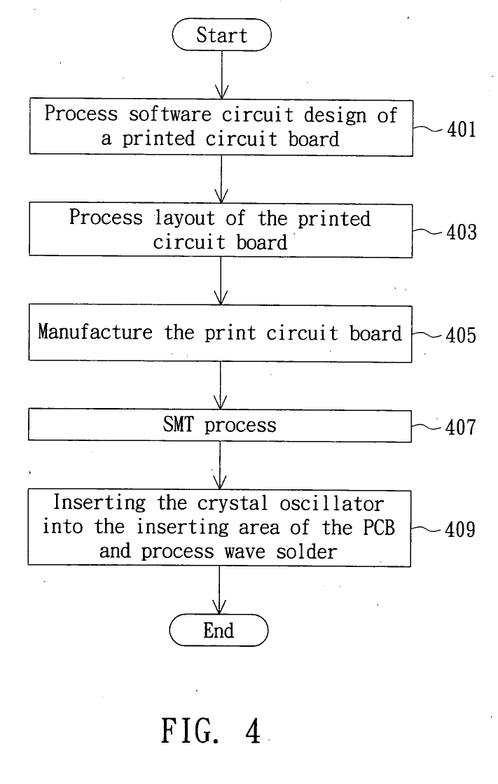

A manufacturing process that incorporates the PCBA and the crystal oscillator is exemplified below. Referring to FIG. 4, a flowchart showing the technology of the invention is shown. The method includes the following steps. Firstly, the method begins at step 401: the circuit design of the PCBA 200 is processed. Next, proceed to step 403: the circuit layout of the PCBA 200 is processed. The step of processing the circuit layout includes the step of reserving the plated holes 210a-210c on the PCB 202 in the software and enabling the inner surface 230 of the plated hole 210a-210c to be electroplated with a coating of metal through software settings. Then, proceed to step 405: the PCB 202 is manufactured. Afterwards, proceed to step 407: the SMT process will be phased in, and lastly, proceed to step 409: the inserting component such as the crystal oscillator 203 is inserted into the PCB 202 and is soldered via wave soldering process. In step 403, the reservation of the plated hole 210a-210c is processed in the software only, and can be done in an instant. In step 409, the plated holes 210a-210c pass through the PCBA 200, the solder 309 is drawn through the plated hole 210a-210c from bottom to up for enabling the shell of the crystal oscillator 203 to electrically connected to the ground layer of the PCB 202. Of course, the aforementioned manufacturing process is applicable to the first embodiment as well as the second embodiment. As long as the plated hole is hollowed through, the aforementioned manufacturing process can be applied to enable the metal shell of the crystal oscillator to be electrically connected to the ground layer of the PCBA.

The crystal oscillator and its corresponding PCBA disclosed in the above embodiment of the invention reserves a plated hole on the PCBA beforehand. The shell of the crystal oscillator and the ground layer of the PCBA are not soldered together via manual soldering process, but rather, the shell of the crystal oscillator is electrically connected to the ground layer of the PCBA during the wave soldering process of the PCBA via the solder which is drawn bottom to up via the plated hole. Therefore, the poor contact between the shell and the bare copper of the inserting area due to the crippling of the crystal oscillator is avoided. Thus, the manufacturing process and the products manufactured using the same can have higher precision; meanwhile, the time, labor and cost involved in manual soldering are largely reduced.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A printed circuit board assembly, comprising:
At lease one crystal oscillator, comprising:
a body;
a shell for covering the body; and
a print circuit board (PCB) , comprising:
at least one ground layer;
at least one inserting area disposed on one side of the printed circuit board for receiving the body; and
at least one plated hole disposed on the inserting area, wherein when the printed circuit board assembly is under wave soldering process, the solder is drawn from another side of the printed circuit board via the plated hole to the side of the printed circuit board assembly where the crystal oscillator is received, so that the shell is electrically connected to the ground layer.

2. The PCBA according to claim 1, wherein the PCB comprises the plurality of ground layers, the plated hole is directly and electrically connected to each ground layer of the PCBA.

3. The PCBA according to claim 1, wherein the plated hole can be of any shape.

4. The PCBA according to claim 1, wherein the inserting area comprises a pre-soldering area on which the plated hole is disposed.

5. The PCBA according to claim 1, wherein the inserting area is bare copper.

6. A method for fixing a crystal oscillator on a print circuit board (PCB) to prevent EMI effect, wherein the crystal oscillator has a shell, the PCB comprises at least one inserting area and at least one ground layer, and the method comprises:
providing the PCB having at least a plated hole disposed thereon; and
inserting the crystal oscillator into the inserting area of the PCB,
wherein the shell is electrically connected to the ground layer via the solder through the plated hole from bottom to up to prevent EMI effect.

7. The method according to claim 6, wherein the step of providing the PCB further comprises:
processing software circuit design of the PCB;
reserving the plated hole on the PCB during software layout; and
manufacturing the PCB.

8. The method according to claim 6, wherein the plated hole is directly and electrically connected to the ground layer of the PCB.

9. The method according to claim 6, wherein the plated hole can be of any shapes.
